(19) United States
(12) Patent Application Publication
(10) Pub. No.: US 2025/0202339 A1
(43) Pub. Date: Jun. 19, 2025

(54) SEMICONDUCTOR DEVICE

(71) Applicant: Mitsubishi Electric Corporation, Tokyo (JP)

(72) Inventor: Ikumi FUKUDA, Tokyo (JP)

(73) Assignee: Mitsubishi Electric Corporation, Tokyo (JP)

(21) Appl. No.: 18/886,179

(22) Filed: Sep. 16, 2024

(30) Foreign Application Priority Data
Dec. 13, 2023 (JP) 2023-209859

(51) Int. Cl. H02M 1/00; H01L 25/07; H02M 7/00

(52) U.S. Cl. CPC H02M 1/0083; H01L 25/072; H02M 7/003

(57) ABSTRACT

A semiconductor device relating technology disclosed herein includes: a substrate; three P input terminals provided on the substrate; three N input terminals provided on the substrate; and an output terminal provided on the substrate. The P input terminals, the N input terminals, and the output terminal are arranged in a straight line in that order in a longitudinal direction of the substrate.

### BACKGROUND OF THE INVENTION

### Field of the Invention

Technology disclosed herein relates to semiconductor technology.

### Description of the Background Art

In a power semiconductor module typified by an insulated gate bipolar transistor (IGBT) module, an intelligent power module (IPM), or a transfer-molded power module (TPM), currents are generally increasingly densified due to miniaturization of a package, and a quantity of a current flowing per module tends to increase.

Heat generated by a contact resistance between terminals and a bus bar, which conventionally has little influence, is thus no longer negligible due to the increase in quantity of the current, and an operation condition of an inverter and the like is sometimes forced to be eased due to heat generation of the terminals.

To address this problem, Japanese Patent Application Laid-Open No. 2023-29342 shows a structure in which a P terminal and an N terminal are provided in view of a height of a bus bar to enable connection to a module with the bus bar being flat, and, as a result, to enable securement of a sufficient area of contact with the terminals, for example.

Japanese Patent Application Laid-Open No. 2023-29342 shows a configuration in which the PN terminals have a different height in view of a thickness of the bus bar, but the configuration has a problem in that design of the bus bar is restricted due to a relationship with the height of the PN terminals.

### SUMMARY

Technology disclosed herein is technology for easing a restriction on design of a bus bar while reducing a contact resistance between terminals and the bus bar.

A semiconductor device as a first aspect of technology disclosed herein includes: a substrate; three P input terminals provided on the substrate; three N input terminals provided on the substrate; and an output terminal provided on the substrate, wherein the P input terminals, the N input terminals, and the output terminal are arranged in a straight line in that order in a longitudinal direction of the substrate.

According at least to the first aspect of the technology disclosed herein, concentration of the amount of heat can be suppressed without adding a restriction to design of a bus bar by increasing the number of input terminals and increasing the number of current paths on an input side for distribution.

These and other objects, features, aspects and advantages of the present invention will become more apparent from the following detailed description of the present invention when taken in conjunction with the accompanying drawings.

### BRIEF DESCRIPTION OF THE DRAWINGS

FIG. 1 is a plan view illustrating an example of a configuration of a semiconductor device according to an embodiment;

FIG. 2 is a plan view illustrating an example of arrangement of terminals of a power semiconductor module illustrated in FIG. 1;

FIG. 3 is a plan view illustrating another example of arrangement of the terminals of the power semiconductor module illustrated in FIG. 1;

FIG. 4 is a perspective view illustrating an example of a structure of the terminals of the power semiconductor module illustrated in FIG. 3;

FIG. 5 is a side view illustrating an example of a configuration of an N bus bar provided in contact with an upper surface and a side surface; and

FIG. 6 is a perspective view illustrating an example of a configuration of a power semiconductor module according to an embodiment.

### DESCRIPTION OF THE PREFERRED EMBODIMENTS

Embodiments will be described below with reference the accompanying drawings. While detailed features and the like are shown in the embodiments below for description of technology, they are examples and are not necessary features to implement the embodiments.

The drawings are schematically shown, and components are omitted or simplified in the drawings as appropriate for convenience of description. The sizes of and a positional interrelationship among components and the like shown in different drawings are not necessarily accurate and can be changed as appropriate. Hatching is sometimes applied to drawings other than a cross-sectional view, such as a plan view, for ease of understanding of the embodiments.

In description made below, similar components bear the same reference signs and have similar names and functions. Detailed description thereof is thus sometimes omitted to avoid redundancy.

In description made herein, an expression “comprising”, “including”, or “having” a certain component is not an exclusive expression excluding the presence of the other components unless otherwise noted.

In description made herein, ordinal numbers, such as “first” and “second”, are used for the sake of convenience for ease of understanding of the embodiments, and the embodiments are not limited to an order that can be represented by the ordinal numbers and the like.

In description made herein, expressions such as “a positive . . . axis direction” and “a negative . . . axis direction” respectively represent a positive direction along an arrow of an illustrated . . . axis and a negative direction opposite the direction along the arrow of the illustrated . . . axis.

In description made herein, terms representing specific positions or directions, such as “upper”, “lower”, “left”, “right”, “side”, “bottom”, “front”, and “back”, may be used, but these terms are used for the sake of convenience for ease of understanding of the embodiments and do not relate to positions or directions in actual implementation of the embodiments.

In description made herein, a phrase “an upper surface of . . . ” or “a lower surface of . . . ” includes not only an upper surface or a lower surface of a target component itself but also a state of another component being formed on the upper surface or the lower surface of the target component. That is to say, a phrase “A provided on an upper surface of B” does not prevent another component “C” from being interposed between A and B, for example.

### First Embodiment

A semiconductor device according to the present embodiment will be described below.

### <Configuration of Semiconductor Device>

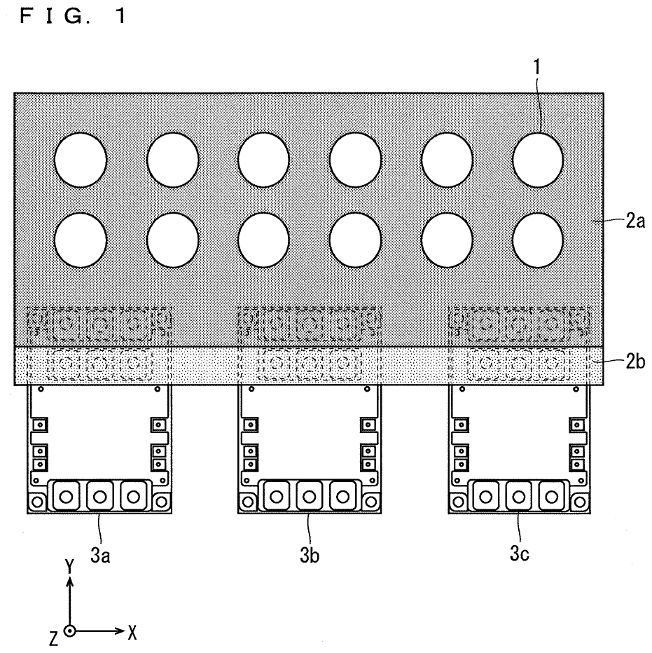

FIG. 1 is a plan view illustrating an example of a configuration of a semiconductor device according to the present embodiment. As illustrated in FIG. 1, a power semiconductor module 3a, a power semiconductor module 3b, and a power semiconductor module 3c are each connected to a P bus bar 2a and an N bus bar 2b. The P bus bar 2a and the N bus bar 2b are arranged to partially overlap each other in plan view while being spaced apart from each other.

A plurality of capacitors 1 connected in parallel are provided on the P bus bar 2a and the N bus bar 2b. The capacitors 1 each have a positive electrode connected to the P bus bar 2a and a negative electrode connected to the N bus bar 2b.

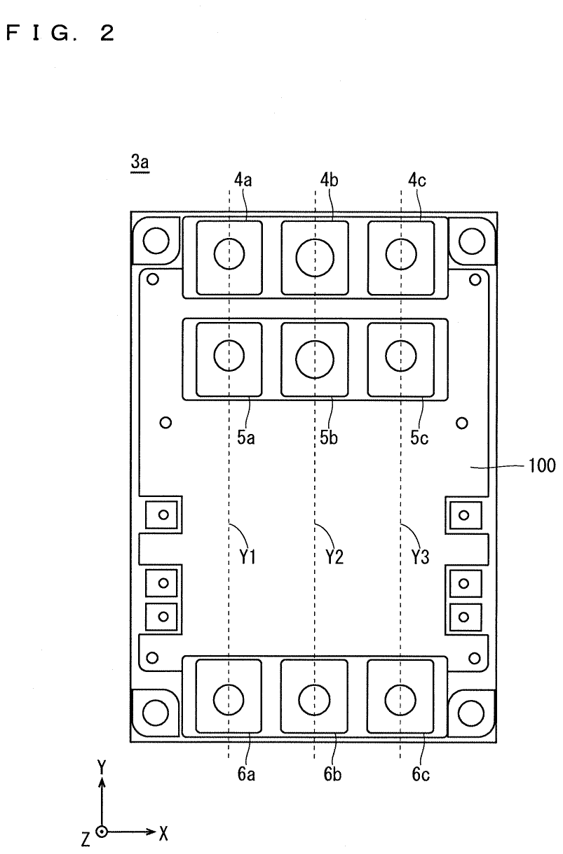

FIG. 2 is a plan view illustrating an example of arrangement of terminals of the power semiconductor module 3a illustrated in FIG. 1. As illustrated in FIG. 2, the power semiconductor module 3a includes a P input terminal 4a, a P input terminal 4b, a P input terminal 4c, an N input terminal 5a, an N input terminal 5b, an N input terminal 5c, an AC output terminal 6a, an AC output terminal 6b, and an AC output terminal 6c provided on a substrate 100. The P input terminal 4a, the P input terminal 4b, and the P input terminal 4c are provided independently of one another. Similarly, the N input terminal 5a, the N input terminal 5b, and the N input terminal 5c are provided independently of one another. Similarly, the AC output terminal 6a, the AC output terminal 6b, and the AC output terminal 6c are provided independently of one another.

The substrate 100 includes a semiconductor substrate having an element structure and a wiring structure on an upper surface thereof.

In the present embodiment, the P input terminal 4b and the N input terminal 5b, which are not provided on the substrate 100 in a conventional configuration, are included to distribute a current in the vicinity of the input terminals, so that the amount of heat generated in the portion can be suppressed.

The P input terminal 4a, the P input terminal 4b, and the P input terminal 4c are connected to the P bus bar 2a as laminated. The N input terminal 5a, the N input terminal 5b, and the N input terminal 5c are connected to the N bus bar 2b as laminated.

The P input terminal 4a, the N input terminal 5a, and the AC output terminal 6a are arranged in a straight line (arranged on an axis Y1) in that order along a longitudinal direction of the module (a Y-axis direction in FIG. 2). Similarly, the P input terminal 4b, the N input terminal 5b, and the AC output terminal 6b are arranged in a straight line (arranged on an axis Y2) in that order along the longitudinal direction of the module. Similarly, the P input terminal 4c, the N input terminal 5c, and the AC output terminal 6c are arranged in a straight line (arranged on an axis Y3) in that order along the longitudinal direction of the module.

It is herein desirable that the P and N input terminals and the AC output terminals be provided opposite each other at ends in a longitudinal direction of the substrate 100.

### Second Embodiment

A semiconductor device according to the present embodiment will be described. In description made below, similar components to those described in the embodiment described above bear the same reference signs as those of the similar components, and detailed description thereof will be omitted as appropriate.

### <Configuration of Semiconductor Device>

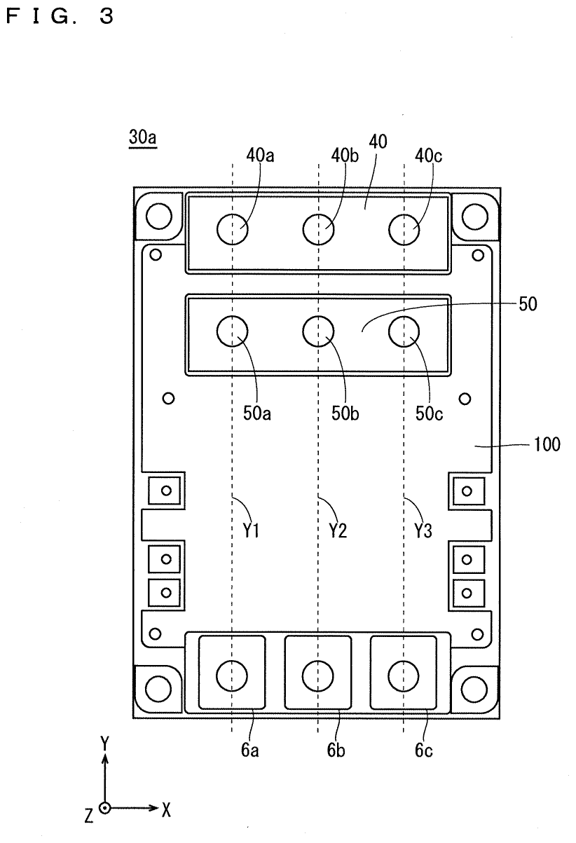

FIG. 3 is a plan view illustrating another example of arrangement of the terminals of the power semiconductor module illustrated in FIG. 1. As illustrated in FIG. 3, a power semiconductor module 30a includes a P input terminal 40a, a P input terminal 40b, a P input terminal 40c, an N input terminal 50a, an N input terminal 50b, an N input terminal 50c, the AC output terminal 6a, the AC output terminal 6b, and the AC output terminal 6c. The P input terminal 40a, the P input terminal 40b, and the P input terminal 40c are integrally provided on a surface of the module via a plate 40 (i.e., provided to be electrically connected to one another). Similarly, the N input terminal 50a, the N input terminal 50b, and the N input terminal 50c are integrally provided on the surface of the module via a plate 50 (i.e., provided to be electrically connected to one another).

The terminals are electrically connected to one another on the surface of the module, so that current imbalance among the terminals can be prevented. As a result, an increase in temperature due to heat generation of the terminals can be suppressed.

### Third Embodiment

A semiconductor device according to the present embodiment will be described. In description made below, similar components to those described in the embodiments described above bear the same reference signs as those of the similar components, and detailed description thereof will be omitted as appropriate.

### <Configuration of Semiconductor Device>

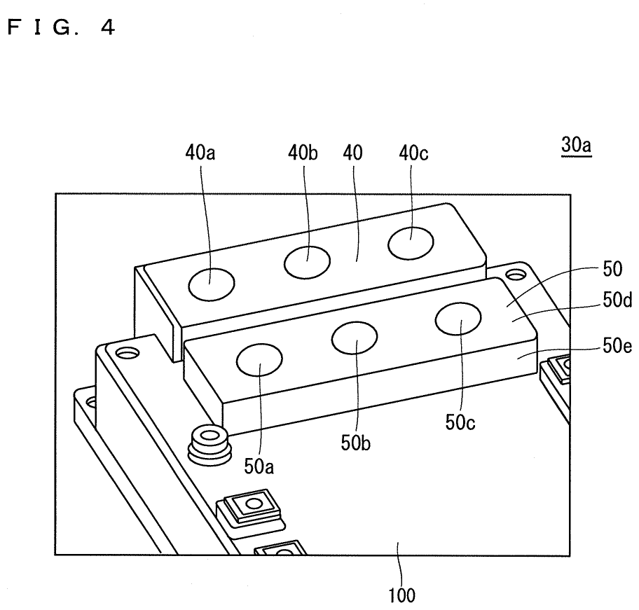

FIG. 4 is a perspective view illustrating an example of the structure of the terminals of the power semiconductor module 30a illustrated in FIG. 3. As illustrated in FIG. 4, the N input terminal 50a, the N input terminal 50b, and the N input terminal 50c have an upper surface 50d and a side surface 50e integrally formed via the plate 50. Assume herein that the side surface 50e is the farthest surface from the P bus bar 2a, that is, a surface of the N input terminal 50a, the N input terminal 50b, and the N input terminal 50c opposite a surface facing the P input terminal 40a, the P input terminal 40b, and the P input terminal 40c.

While the N bus bar 2b is provided in contact with only the upper surface 50d in the example illustrated in FIG. 3, the N bus bar is provided in contact with not only the upper surface 50d but also the side surface 50e in the example illustrated in FIG. 4.

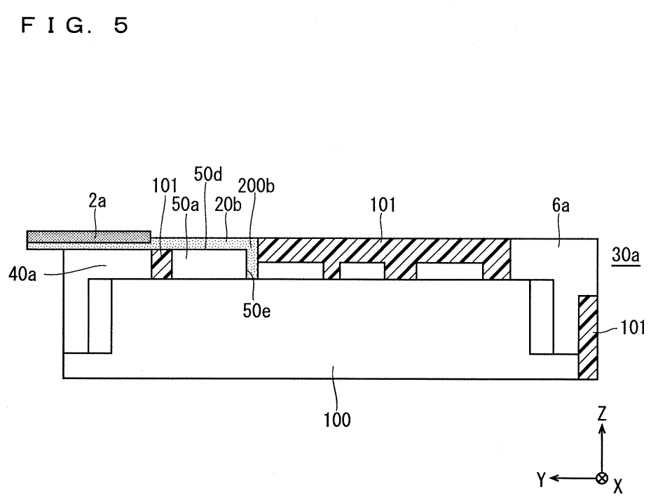

FIG. 5 is a side view illustrating an example of a configuration of the N bus bar provided in contact with the upper surface 50d and the side surface 50e. As illustrated in FIG. 5, an N bus bar 20b has a bend 200b having been bent 900 and thus can be in contact with the upper surface 50d and the side surface 50e. The N bus bar 2b has an opening (not illustrated herein) in a portion where the P bus bar 2a and the P input terminal 40a are in contact with each other, so that the P bus bar 2a can be in contact with the P input terminal 40a without being in contact with the N bus bar 2b.

### Fourth Embodiment

A semiconductor device according to the present embodiment will be described. In description made below, similar components to those described in the embodiments described above bear the same reference signs as those of the similar components, and detailed description thereof will be omitted as appropriate.

### <Configuration of Semiconductor Device>

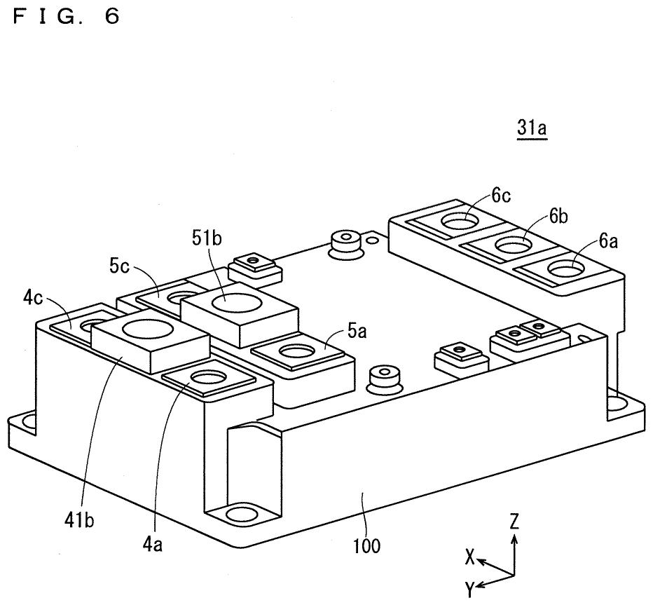

FIG. 6 is a perspective view illustrating an example of a configuration of a power semiconductor module according to the present embodiment. As illustrated in FIG. 6, a power semiconductor module 31a includes the P input terminal 4a, a P input terminal 41b, the P input terminal 4c, the N input terminal 5a, an N input terminal 51b, the N input terminal 5c, the AC output terminal 6a, the AC output terminal 6b, and the AC output terminal 6c. The P input terminal 4a, the P input terminal 41b, and the P input terminal 4c are provided independently of one another. Similarly, the N input terminal 5a, the N input terminal 51b, and the N input terminal 5c are provided independently of one another.

A height of an upper surface of the P input terminal 41b is set to be up to 10 mm greater than a height of an upper surface of the P input terminal 4a and a height of an upper surface of the P input terminal 4c, for example. A height of an upper surface of the N input terminal 51b is also set to be up to 10 mm greater than a height of an upper surface of the N input terminal 5a and a height of an upper surface of the N input terminal 5c, for example.

As illustrated in FIGS. 3 and 4, the P input terminal 4a, the P input terminal 41b, and the P input terminal 4c may integrally be formed via a plate. Similarly, the N input terminal 5a, the N input terminal 51b, and the N input terminal 5c may integrally be formed via a plate.

The height of the upper surface of the P input terminal 41b and the height of the upper surface of the N input terminal 51b are set to be greater than the height of each of the upper surfaces of the other terminals, so that the P input terminal 41b and the N input terminal 51b are fixed without being screwed while receiving sufficient pressure from the bus bar being in contact with the upper surfaces thereof. Thus, even when only the P input terminal 4a, the P input terminal 4c, the N input terminal 5a, and the N input terminal 5c are screwed for fixation, sufficient pressure is applied to surfaces of contact of the P input terminal 41b and the N input terminal 51b with the bus bar, so that a current flows appropriately from the P input terminal 41b and the N input terminal 51b to suppress heat generation of the terminals.

### <Effects Produced by Embodiments Described Above>

Examples of effects produced by the embodiments described above will be shown next. In description made below, the effects will be described based on a specific configuration whose examples are shown in the embodiments described above, but the specific configuration may be replaced with another specific configuration whose example is shown herein to the extent that similar effects are produced. That is to say, only one of corresponding specific configurations will sometimes be described as a representative below for the sake of convenience, but the specific configuration described as the representative may be replaced with another corresponding specific configuration.

The replacement may span a plurality of embodiments. That is to say, configurations whose examples are shown in different embodiments may be combined with each other to produce similar effects.

According to the embodiments described above, the semiconductor device includes: the substrate 100; three P input terminals (the P input terminal 4a, the P input terminal 4b, the P input terminal 4c, the P input terminal 40a, the P input terminal 40b, the P input terminal 40c, or the P input terminal 41b) provided on the substrate 100; three N input terminals (the N input terminal 5a, the N input terminal 5b, the N input terminal 5c, the N input terminal 50a, the N input terminal 50b, the N input terminal 50c, or the N input terminal 51b) provided on the substrate 100; and the output terminal (the AC output terminal 6a, the AC output terminal 6b, or the AC output terminal 6c) provided on the substrate 100. The P input terminals, the N input terminals, and the output terminal are arranged in a straight line in that order in the longitudinal direction of the substrate 100.

According to such a configuration, concentration of the amount of heat can be suppressed without adding a restriction to design of the bus bar (without considering the shape of the bus bar to improve heat dissipation) by increasing the number of input terminals and increasing the number of current paths on an input side for distribution.

Heat generation can be suppressed by reducing a value of a contact resistance between the input terminals and the bus bar.

Furthermore, a P input terminal, an N input terminal, and an AC output terminal of each set are arranged in a straight line along a Y-axis direction, so that a path of a current flowing in the Y-axis direction can be expanded to a terminal portion (i.e., can be expanded from a portion where the P input terminal or the N input terminal is disposed to a portion where the AC output terminal is disposed).

As a result, a range in which a magnetic field generated by di/dt between a first current flowing from the P input terminal to the AC output terminal in a negative Y-axis direction and a second current flowing from the AC output terminal to the N input terminal in a positive Y-axis direction can be cancelled is expanded. A surge voltage can thus be suppressed.

Similar effects can be produced when another configuration whose example is shown herein is added to the above-mentioned configuration as appropriate, that is, when another configuration herein not referred to as the above-mentioned configuration is added to the above-mentioned configuration as appropriate.

According to the embodiments described above, the P input terminal 40a, the P input terminal 40b, and the P input terminal 40c are electrically connected to one another via the plate 40 to be integrally provided. The N input terminal 50a, the N input terminal 50b, and the N input terminal 50c are electrically connected to one another via the plate 50 to be integrally provided. According to such a configuration, the input terminals are electrically connected to one another on the surface of the semiconductor module, so that current imbalance among the input terminals can be suppressed. The input terminals are integrated, so that electrical connection between the bus bar and the input terminals can be facilitated without leaving a resin among the input terminals, and thus the contact resistance between the bus bar and the input terminals can be reduced.

According to the embodiments described above, the integrally provided N input terminals have the upper surface 50d and the side surface 50e. The side surface 50e of the N input terminals is the surface opposite the surface facing the integrally provided P input terminals. The semiconductor device further includes the N bus bar 20b provided in contact with the upper surface 50d and the side surface 50e of the integrally provided N input terminals. According to such a configuration, the area of contact between the N bus bar 20b and the N input terminals 50a, 50b, and 50c can be increased, so that heat generation of the terminals can be suppressed.

According to the embodiments described above, the P input terminals include a first P input terminal, a second P input terminal, and a third P input terminal. Herein, the first P input terminal corresponds to the P input terminal 4a and the like, for example. The second P input terminal corresponds to the P input terminal 41b and the like, for example. The third P input terminal corresponds to the P input terminal 4c and the like, for example. The P input terminal 4a, the P input terminal 41b, and the P input terminal 4c are arranged in a straight line in that order. The height of the upper surface of the P input terminal 41b is greater than the height of the upper surface of the P input terminal 4a and the height of the upper surface of the P input terminal 4c, and the height of the upper surface of the P input terminal 41b has a difference from the height of the upper surface of the P input terminal 4a and the height of the upper surface of the P input terminal 4c of 10 mm or less. The N input terminals include a first N input terminal, a second N input terminal, and a third N input terminal. Herein, the first N input terminal corresponds to the N input terminal 5a and the like, for example. The second N input terminal corresponds to the N input terminal 51b and the like, for example. The third N input terminal corresponds to the N input terminal 5c and the like, for example. The N input terminal 5a, the N input terminal 51b, and the N input terminal 5c are arranged in a straight line in that order. The height of the upper surface of the N input terminal 51b is greater than the height of the upper surface of the N input terminal 5a and the height of the upper surface of the N input terminal 5c, and the height of the upper surface of the N input terminal 51b has a difference from the height of the upper surface of the N input terminal 5a and the height of the upper surface of the N input terminal 5c of 10 mm or less. According to such a configuration, the upper surface of the input terminal at the center (the P input terminal 41b and the N input terminal 51b) is set to be higher than the upper surfaces of the other input terminals (the P input terminal 4a, the P input terminal 4c, the N input terminal 5a, and the N input terminal 5c), so that the P input terminal 41b and the N input terminal 51b are fixed without being screwed by receiving sufficient pressure. The current flows appropriately from the P input terminal 41b and the N input terminal 51b, so that heat generation of the terminals can be suppressed.

### Modifications of Embodiments Described Above

In the embodiments described above, material properties of, materials for, dimensions of, shapes of, a relative positional relationship among, or conditions for implementation of components are sometimes described, but they are each one example in all aspects, and are not restrictive.

Numerous modifications and the equivalent whose examples are not shown are thus devised within the scope of technology disclosed herein. For example, a case where at least one component is modified, added, or omitted and, further, a case where at least one component in at least one embodiment is extracted to be combined with components in another embodiment are included.

In a case where a name of a material and the like are described in at least one of the embodiments described above without being particularly designated, an alloy and the like containing an additive in addition to the material may be included unless any contradiction occurs.

“One” component in the embodiments described above may include “one or more” components unless any contradiction occurs.

Furthermore, each component in the embodiments described above is a conceptual unit, and a case where one component includes a plurality of structures, a case where one component corresponds to a portion of a structure, and a case where a plurality of components are included in one structure are included within the scope of technology disclosed herein.

Each component in the embodiments described above includes a structure having another structure or shape as long as the same function is fulfilled.

Description made herein is referred to for all the purposes relating to the present technology and is not admitted to be prior art.

Various aspects of the present disclosure will collectively be described below as appendices.

### Appendix 1

A semiconductor device comprising:
a substrate;
three P input terminals provided on the substrate;
three N input terminals provided on the substrate; and
an output terminal provided on the substrate, wherein
the P input terminals, the N input terminals, and the output terminal are arranged
in a straight line in that order in a longitudinal direction of the substrate.

### Appendix 2

The semiconductor device according to Appendix 1, wherein
the three P input terminals are electrically connected to one another via a first plate to be integrally provided, and
the three N input terminals are electrically connected to one another via a second plate to be integrally provided.

### Appendix 3

The semiconductor device according to Appendix 2, wherein
the integrally provided N input terminals have an upper surface and a side surface,
the side surface of the N input terminals is a surface opposite a surface facing the integrally provided P input terminals, and
the semiconductor device further comprises
   an N bus bar provided in contact with the upper surface and the side surface of the integrally provided N input terminals.

### Appendix 4

The semiconductor device according to any one of Appendices 1 to 3, wherein
the P input terminals include a first P input terminal, a second P input terminal, and a third P input terminal,
the first P input terminal, the second P input terminal, and the third P input terminal are arranged in a straight line in that order,
a height of an upper surface of the second P input terminal is greater than a height of an upper surface of the first P input terminal and a height of an upper surface of the third P input terminal,
the height of the upper surface of the second P input terminal has a difference from the height of the upper surface of the first P input terminal and the height of the upper surface of the third P input terminal of 10 mm or less,
the N input terminals include a first N input terminal, a second N input terminal, and a third N input terminal,
the first N input terminal, the second N input terminal, and the third N input terminal are arranged in a straight line in that order,
a height of an upper surface of the second N input terminal is greater than a height of an upper surface of the first N input terminal and a height of an upper surface of the third N input terminal, and
the height of the upper surface of the second N input terminal has a difference from the height of the upper surface of the first N input terminal and the height of the upper surface of the third N input terminal of 10 mm or less.

While the invention has been shown and described in detail, the foregoing description is in all aspects illustrative and not restrictive. It is therefore understood that numerous modifications and variations can be devised without departing from the scope of the invention.

What is claimed is:

1. A semiconductor device comprising:
a substrate;
three P input terminals provided on the substrate;
three N input terminals provided on the substrate; and
an output terminal provided on the substrate, wherein
the P input terminals, the N input terminals, and the output terminal are arranged in a straight line in that order in a longitudinal direction of the substrate.

2. The semiconductor device according to claim 1, wherein
the three P input terminals are electrically connected to one another via a first plate to be integrally provided, and
the three N input terminals are electrically connected to one another via a second plate to be integrally provided.

3. The semiconductor device according to claim 2, wherein
the integrally provided N input terminals have an upper surface and a side surface,
the side surface of the N input terminals is a surface opposite a surface facing the integrally provided P input terminals, and
the semiconductor device further comprises
an N bus bar provided in contact with the upper surface and the side surface of the integrally provided N input terminals.

4. The semiconductor device according to claim 1, wherein
the P input terminals include a first P input terminal, a second P input terminal, and a third P input terminal,
the first P input terminal, the second P input terminal, and the third P input terminal are arranged in a straight line in that order,
a height of an upper surface of the second P input terminal is greater than a height of an upper surface of the first P input terminal and a height of an upper surface of the third P input terminal,
the height of the upper surface of the second P input terminal has a difference from the height of the upper surface of the first P input terminal and the height of the upper surface of the third P input terminal of 10 mm or less,
the N input terminals include a first N input terminal, a second N input terminal, and a third N input terminal,
the first N input terminal, the second N input terminal, and the third N input terminal are arranged in a straight line in that order,
a height of an upper surface of the second N input terminal is greater than a height of an upper surface of the first N input terminal and a height of an upper surface of the third N input terminal, and
the height of the upper surface of the second N input terminal has a difference from the height of the upper surface of the first N input terminal and the height of the upper surface of the third N input terminal of 10 mm or less.

5. The semiconductor device according to claim 2, wherein
the P input terminals include a first P input terminal, a second P input terminal, and a third P input terminal,
the first P input terminal, the second P input terminal, and the third P input terminal are arranged in a straight line in that order,
a height of an upper surface of the second P input terminal is greater than a height of an upper surface of the first P input terminal and a height of an upper surface of the third P input terminal,
the height of the upper surface of the second P input terminal has a difference from the height of the upper surface of the first P input terminal and the height of the upper surface of the third P input terminal of 10 mm or less,
the N input terminals include a first N input terminal, a second N input terminal, and a third N input terminal,
the first N input terminal, the second N input terminal, and the third N input terminal are arranged in a straight line in that order,
a height of an upper surface of the second N input terminal is greater than a height of an upper surface of the first N input terminal and a height of an upper surface of the third N input terminal, and
the height of the upper surface of the second N input terminal has a difference from the height of the upper surface of the first N input terminal and the height of the upper surface of the third N input terminal of 10 mm or less.

6. The semiconductor device according to claim 3, wherein
the P input terminals include a first P input terminal, a second P input terminal, and a third P input terminal,
the first P input terminal, the second P input terminal, and the third P input terminal are arranged in a straight line in that order,
a height of an upper surface of the second P input terminal is greater than a height of an upper surface of the first P input terminal and a height of an upper surface of the third P input terminal,
the height of the upper surface of the second P input terminal has a difference from the height of the upper surface of the first P input terminal and the height of the upper surface of the third P input terminal of 10 mm or less,
the N input terminals include a first N input terminal, a second N input terminal, and a third N input terminal,
the first N input terminal, the second N input terminal, and the third N input terminal are arranged in a straight line in that order,
a height of an upper surface of the second N input terminal is greater than a height of an upper surface of the first N input terminal and a height of an upper surface of the third N input terminal, and
the height of the upper surface of the second N input terminal has a difference from the height of the upper surface of the first N input terminal and the height of the upper surface of the third N input terminal of 10 mm or less.
